(19) United States
(12) Patent Application Publication
(10) Pub. No.: US 2026/0284698 A1
(43) Pub. Date: Sep. 24, 2026

(54) SUBSTRATE PROCESSING APPARATUS

(71) Applicant: SCREEN Holdings Co., Ltd., Kyoto (JP)

(72) Inventor: Yoshinori TAWARATANI, Kyoto-shi (JP)

(21) Appl. No.: 19/563,852

(22) Filed: Mar. 11, 2026

(30) Foreign Application Priority Data
Mar. 21, 2025 (JP) 2025-046905

(51) Int. Cl. B05C 11/10; B05C 5/02; B05C 11/08; B05C 13/00; B08B 9/00; G03F 7/16

(52) U.S. Cl. CPC B05C 11/1039; B05C 5/02; B05C 11/08; B05C 13/00; B08B 9/00; G03F 7/162

(57) ABSTRACT

A substrate processing apparatus includes a solvent scattering mechanism scattering a solvent outward in a rotation radius direction of a spin chuck, cooperating with a rotation mechanism, and a cup. The cup includes an upper cup, a lower cup in which drainage and exhaust areas are provided separately, and a middle cup disposed in a ring shape between the upper and lower cups to cover an upper side of the exhaust area of the lower cup. The middle cup is inclined downward from its outer peripheral end portion toward its inner peripheral end portion, can receive a coating liquid and the solvent having flowed down along an inner surface of the upper cup on an outer peripheral end portion side, and causes the received coating liquid and the solvent to flow downward to an inner peripheral end portion side to be guided to the drainage area of the lower cup.

### CROSS-REFERENCE TO RELATED APPLICATIONS

This application claims priority to Japanese Patent Application No. 2025-046905 filed Mar. 21, 2025, the subject matter of which is incorporated herein by reference in entirety.

### BACKGROUND

### Technical Field

The present invention relates to a substrate processing apparatus that processes a substrate. Examples of the substrate include a semiconductor substrate, a substrate for a flat panel display (FPD), a glass substrate for a photomask, a substrate for an optical disk, a substrate for a magnetic disk, a ceramic substrate, and a substrate for a solar cell. Examples of the FPD include a liquid crystal display device and an organic electroluminescence (EL) display device.

### Related Art

Conventionally, a substrate processing apparatus includes a spin chuck that holds a substrate and a cup that recovers a coating liquid scattered from the substrate held by the spin chuck. The cup includes an upper cup surrounding a side of the substrate, a lower cup coupled to a lower side of the upper cup, and a middle cup provided between the upper cup and the lower cup (see, for example, JP 2001-176767 A).

The lower cup is divided into a drainage area for draining the coating liquid and an exhaust area for exhausting an inside of the cup. The middle cup (referred to as a flow straightening plate in JP 2001-176767 A) prevents the scattered coating liquid from flowing into the exhaust area. The middle cup includes an inclined surface inclined in a downward direction from an inner peripheral side toward an outer peripheral side. The middle cup guides a scattered chemical liquid to the drainage area of the lower cup along the inclined surface. In addition, for example, a flow path for causing the coating liquid to flow is formed between an outer peripheral end of the middle cup and an outer peripheral wall of the upper cup.

### SUMMARY

In recent years, a high-viscosity coating liquid is used for forming a thick film on a substrate. As a viscosity of a coating liquid increases, a maintenance cycle (for example, a cycle of cup replacement) tends to be shortened.

A coating liquid scattered from a substrate adheres to and accumulates on an upper surface of a middle cup. A high-viscosity coating liquid hardly flows, and the coating liquid is dried, so that an amount of the coating liquid adhering to the upper surface of the middle cup increases. A surface of the coating liquid accumulated on the upper surface of the middle cup has unevennesses. Therefore, the coating liquid scattered from the substrate may hit the coating liquid accumulated on the upper surface of the middle cup to bounce back, and adhere to a coating film on the substrate again. As a result, a defect occurs in the coating film.

Therefore, it is desirable to clean the upper surface of the middle cup. For example, after the coating film is formed on an upper surface of the substrate, a back-rinse treatment is performed. In the back-rinse treatment, a solvent is supplied to a lower surface of the rotating substrate to clean the lower surface of the substrate. Here, the solvent supplied to the lower surface of the substrate is scattered into an upper cup by a centrifugal force due to the rotation of the substrate. However, the solvent scatters in a substantially horizontal direction from the rotating substrate. Therefore, the solvent hardly hits the upper surface of the middle cup.

In addition, a cup cleaning disk periodically supplies a solvent into the upper cup in order to clean the upper cup and the upper surface of the middle cup. However, when there is a long interval until the next cleaning, the coating liquid accumulated on the upper surface of the middle cup is further dried. This makes it difficult to remove the coating liquid from the upper surface of the middle cup. The cleaning by the cup cleaning disk is not performed when the coating liquid is applied to the upper surface of the substrate, that is, when a semiconductor or the like is manufactured.

Therefore, since it is not possible to suppress the coating liquid from accumulating on the upper surface of the middle cup, a maintenance cycle (for example, a cycle of cup replacement) is shortened.

JP 2001-176767 A discloses that an organic solvent such as thinner is supplied from a liquid supply unit inside the flow straightening plate (middle cup) to an upper surface of the flow straightening plate through a supply hole. However, a structure of the middle cup may be complicated.

The present invention has been made in view of such circumstances, and an object thereof is to provide a substrate processing apparatus capable of suppressing a coating liquid from accumulating on an upper surface of a middle cup.

In order to achieve such an object, the present invention has the following configuration. That is, a substrate processing apparatus configured to apply a coating liquid to a substrate, according to the present invention includes: a chuck configured to hold the substrate in a horizontal posture; a rotation mechanism configured to rotate the chuck about a vertical axis passing through a center of the substrate held by the chuck; a coating liquid nozzle configured to discharge the coating liquid to an upper surface of the substrate held by the chuck; a solvent scattering mechanism configured to scatter a solvent outward in a rotation radius direction of the chuck, in cooperation with the rotation mechanism; and a cup configured to recover the scattered solvent, in which the cup includes an upper cup provided so as to surround a side of the substrate held by the chuck, a lower cup that is a ring-shaped container provided below the upper cup, a drainage area and an exhaust area being provided separately in the container, and a middle cup disposed in a ring shape between the upper cup and the lower cup so as to cover an upper side of the exhaust area of the lower cup, and the middle cup is inclined downward from an outer peripheral end portion of the middle cup toward an inner peripheral end portion of the middle cup, is capable of receiving the coating liquid and the solvent that have flowed down along an inner surface of the upper cup on a side of the outer peripheral end portion, and is configured to cause the received coating liquid and the solvent to flow downward to a side of the inner peripheral end portion to be guided to the drainage area of the lower cup.

According to the substrate processing apparatus of the present invention, the middle cup is inclined downward from its outer peripheral end portion toward its inner peripheral end portion, and is capable of receiving the coating liquid and the solvent that have flowed down along the inner surface of the upper cup on the side of the outer peripheral end portion of the middle cup. In addition, the received coating liquid and the solvent are caused to flow downward to the side of the inner peripheral end portion and guided to the drainage area of the lower cup. As a result, the solvent received on an inner side surface of the upper cup can be caused to flow to substantially the entire upper surface of the middle cup from the outer peripheral end portion to the inner peripheral end portion of the middle cup. Therefore, it is possible to cause the coating liquid and the solvent to flow along the inclination of the middle cup while suppressing drying of the coating liquid adhering to the upper surface of the middle cup. As a result, it is possible to suppress the coating liquid from accumulating on the upper surface of the middle cup. As a result, a maintenance cycle (for example, a cycle of cup replacement) can be lengthened. In addition, since the middle cup covers the upper side of the exhaust area, it is possible to suppress the coating liquid and the solvent from flowing into the exhaust pipe.

In the substrate processing apparatus described above, it is preferable that the outer peripheral end portion of the middle cup is coupled to the inner surface of the upper cup. Since the outer peripheral end portion of the middle cup is coupled to the inner surface of the upper cup, all of the solvent that has flowed down along the inner surface of the upper cup can be caused to flow to substantially the entire upper surface of the middle cup.

In the substrate processing apparatus described above, it is preferable that the middle cup is configured to form a gap between the inner peripheral end portion of the middle cup and an inner peripheral wall of the lower cup. The gap between the inner peripheral end portion of the middle cup and the inner peripheral wall of the lower cup can guide the coating liquid and the solvent to the drainage area and can guide gas to the exhaust area.

In the substrate processing apparatus described above, it is preferable that the gap is located below an outer peripheral end of the substrate. Since the gas flows in a relatively vertical downward direction to the gap between the inner peripheral end portion of the middle cup and the inner peripheral wall of the lower cup from near the outer peripheral end of the substrate, for example, the gas including a mist of the coating liquid can be caused to flow smoothly.

In the substrate processing apparatus described above, it is preferable that the middle cup is configured to form the gap extending in a downward direction with the inner peripheral wall of the lower cup as a distal end of the inner peripheral end portion of the middle cup hangs down in a vertical downward direction. Since the gap extends in the downward direction between the inner peripheral end portion of the middle cup and the inner peripheral wall of the lower cup, it is possible to suppress turbulence of airflow passing through the gap.

In the substrate processing apparatus described above, it is preferable that the solvent scattering mechanism includes a first solvent nozzle configured to discharge the solvent to the substrate held by the chuck, and the rotation mechanism is configured to rotate the substrate held by the chuck about the vertical axis to scatter the solvent discharged to the substrate to an inner side surface of the upper cup.

Every time the substrate is treated with the solvent discharged from the first solvent nozzle (at least one of a pre-wet treatment and a back-rinse treatment, for example), the solvent can be caused to flow to substantially the entire upper surface of the middle cup.

In the substrate processing apparatus described above, it is preferable that the solvent scattering mechanism includes a cup cleaning jig formed in a disk shape, and a first solvent nozzle configured to discharge the solvent to the cup cleaning jig held by the chuck, and the rotation mechanism is configured to rotate the cup cleaning jig held by the chuck about the vertical axis to scatter the solvent discharged to the cup cleaning jig to an inner side surface of the upper cup.

The middle cup is inclined downward from its outer peripheral end portion toward its inner peripheral end portion. For example, it is assumed that the solvent is supplied to the upper surface of the middle cup using the cup cleaning jig held by the chuck and the first solvent nozzle. In this case, if the solvent is scattered to the inner side surface of the upper cup, the solvent can be caused to flow to substantially the entire upper surface of the middle cup. Therefore, it is easy to supply the solvent to the upper surface of the middle cup.

In the substrate processing apparatus described above, it is preferable that the solvent scattering mechanism includes a cup cleaning jig disposed inside the upper cup and below the chuck, and a second solvent nozzle configured to supply the solvent to the cup cleaning jig, and the rotation mechanism is configured to rotate the cup cleaning jig about the vertical axis to scatter the solvent supplied to the cup cleaning jig to an inner side surface of the upper cup.

The middle cup is inclined downward from its outer peripheral end portion toward its inner peripheral end portion. For example, it is assumed that the solvent is supplied to the upper surface of the middle cup using the cup cleaning jig disposed below the chuck and the second solvent nozzle. In this case, if the solvent is scattered to the inner side surface of the upper cup, the solvent can be caused to flow to substantially the entire upper surface of the middle cup. Therefore, it is easy to supply the solvent to the upper surface of the middle cup.

In the substrate processing apparatus described above, it is preferable that the lower cup includes a bottom wall, an exhaust pipe provided on the bottom wall in the exhaust area, and a drain provided on the bottom wall in the drainage area, and the drain is disposed on an outer peripheral side of the exhaust pipe.

For example, the lower cup having the same shape as a lower cup of a developing device that performs development processing can be used. Since a common component (lower cup) can be used, the cost of the substrate processing apparatus can be reduced.

In the substrate processing apparatus described above, it is preferable that the upper cup includes an upper opening disposed in an upper portion and a central portion of the upper cup, the outer peripheral end portion of the middle cup is coupled to the inner surface of the upper cup, the lower cup includes a bottom wall, an exhaust pipe provided on the bottom wall in the exhaust area, a drain provided on the bottom wall in the drainage area, and an inner peripheral wall extending in a cylindrical shape in an upward direction from the bottom wall, and the exhaust pipe is configured to exhaust gas that has flowed in from the upper opening of the upper cup and passed between the inner peripheral end portion of the middle cup and the inner peripheral wall of the lower cup.

The middle cup is inclined downward from its outer peripheral end portion toward its inner peripheral end portion. The outer peripheral end portion of the middle cup is coupled to the inner surface of the upper cup. In addition, the upper opening is disposed in the central portion of the upper cup. As a result, the gas that has flowed in from the upper opening does not go around and easily goes between the inner peripheral end portion of the middle cup and the inner peripheral wall of the lower cup. That is, the gas that has flowed in from the upper opening hardly flows via the inner side surface of the upper cup to a distal end side of the middle cup from the upper opening. Therefore, the coating liquid and the solvent adhering to the upper surface of the middle cup are hardly dried. Therefore, the coating liquid adhering to the upper surface of the middle cup can be caused to easily flow.

In the substrate processing apparatus described above, it is preferable that the cup includes an inner cup configured to extend in a cylindrical shape in the upward direction from an upper end of the inner peripheral wall of the lower cup toward a lower surface of the substrate held by the chuck, the inner cup includes an inner cup body formed in a cylindrical shape, and a flow straightening member formed in a ring shape at an upper end portion of the inner cup body, and an outer peripheral end of the flow straightening member is configured to protrude toward an outer peripheral side more than an outer peripheral end of the substrate held by the chuck.

The gas that has flowed in from the upper opening does not go around and easily goes between the inner peripheral end of the middle cup and the inner peripheral wall of the lower cup. For example, when the outer peripheral end of the substrate held by the chuck protrudes toward an outer peripheral side more than the outer peripheral end of the flow straightening member, the flow of the gas that has flowed in from the upper opening affects the outer peripheral end of the substrate. As a result, a drying condition of the coating liquid near the outer peripheral end of the substrate changes, and a thickness of a coating film near the outer peripheral end of the substrate may change. According to the present invention, the outer peripheral end of the flow straightening member protrudes more than the outer peripheral end of the substrate held by the chuck. As a result, the flow of the gas that has flowed in from the upper opening deviates outward from the outer peripheral end of the substrate. As a result, the change in the drying condition of the coating liquid near the outer peripheral end of the substrate can be suppressed, whereby the change in the thickness of the coating film near the outer peripheral end of the substrate can be suppressed.

In the substrate processing apparatus described above, it is preferable that the upper cup includes an outer peripheral wall formed in a cylindrical shape, and a ceiling wall formed in a ring shape while extending in an inward direction from an upper portion of the outer peripheral wall toward the vertical axis, the ceiling wall includes a trap portion formed in a ring shape in an inner peripheral portion and configured to protrude in a downward direction, and a trap surface is formed on an outer peripheral side of the trap portion.

The trap surface is formed in the cylindrical shape while extending in the vertical direction. Therefore, it is possible to easily capture a mist of at least one of the coating liquid and the solvent flowing toward the substrate held by the chuck along an inner surface of the outer peripheral wall of the upper cup and an inner surface of the ceiling wall.

In the substrate processing apparatus described above, it is preferable that the cup is fixed in position so as not to lift and lower with respect to the chuck. For example, when the cup (upper cup, middle cup, and lower cup) is configured to lift and lower, the substrate processing apparatus may be increased in size. According to the present invention, it is possible to suppress an increase in size of the substrate processing apparatus and to configure the substrate processing apparatus to be relatively compact.

It is preferable that the substrate processing apparatus described above further includes: at least three support pins provided around the vertical axis and configured to support the substrate, the at least three support pins being disposed on an outer peripheral side of the chuck and on an inner peripheral side of the upper cup; and a support pin lifting and lowering mechanism configured to lift and lower the at least three support pins, in which the upper cup includes an upper opening disposed in an upper portion and a central portion of the upper cup, and the support pin lifting and lowering mechanism is configured to lift and lower the substrate between a holding position of an upper surface of the chuck and a transfer position higher than an upper end of the upper cup, through the upper opening.

As a result, the substrate can be placed on the upper surface of the chuck accommodated in the upper cup through the upper opening of the upper cup, and the substrate on the upper surface of the chuck can be taken out from the upper cup through the upper opening of the upper cup.

According to a substrate processing apparatus of the present invention, it is possible to suppress a coating liquid from accumulating on an upper surface of a middle cup.

### BRIEF DESCRIPTION OF DRAWINGS

For the purpose of illustrating the invention, there are shown in the drawings several forms which are presently preferred, it being understood, however, that the invention is not limited to the precise arrangement and instrumentalities shown.

FIG. 1 is a longitudinal sectional view showing a substrate processing apparatus according to a first embodiment;

FIG. 2 is an enlarged longitudinal sectional view of a right portion of a cup shown in FIG. 1;

FIG. 3 is a plan view showing a lower cup;

FIG. 4 is a plan view mainly showing an upper cup, an inner cup, and a substrate;

FIG. 5 is a side view showing a substrate lifting and lowering mechanism;

FIG. 6 is a block diagram showing a configuration related to control;

FIG. 7 is a flowchart showing an example of an operation of the substrate processing apparatus;

FIG. 8 is a partially enlarged longitudinal sectional view of the cup for describing a flow of a solvent;

FIG. 9 is a partially enlarged longitudinal sectional view of the cup for describing how a coating liquid scatters;

FIG. 10 is a partially enlarged longitudinal sectional view of the cup for describing a flow of gas;

FIG. 11 is a longitudinal sectional view for describing a problem in a case where an outer peripheral end of the substrate protrudes more than an outer peripheral end of a flow straightening member of the inner cup;

FIG. 12 is a longitudinal sectional view for describing an effect in a case where the outer peripheral end of the flow straightening member of the inner cup protrudes more than the outer peripheral end of the substrate;

FIG. 13 is a partially enlarged longitudinal sectional view of a cup according to a second embodiment;

FIG. 14 is a longitudinal sectional view showing a substrate processing apparatus according to a third embodiment;

FIG. 15 is a flowchart showing an example of an operation of the substrate processing apparatus according to the third embodiment;

FIG. 16 is a longitudinal sectional view showing a substrate processing apparatus according to a fourth embodiment; and

FIG. 17 is a partially enlarged longitudinal sectional view of a cup according to a modification.

### DETAILED DESCRIPTION

Hereinafter, embodiments of the present invention will be described.

### First embodiment

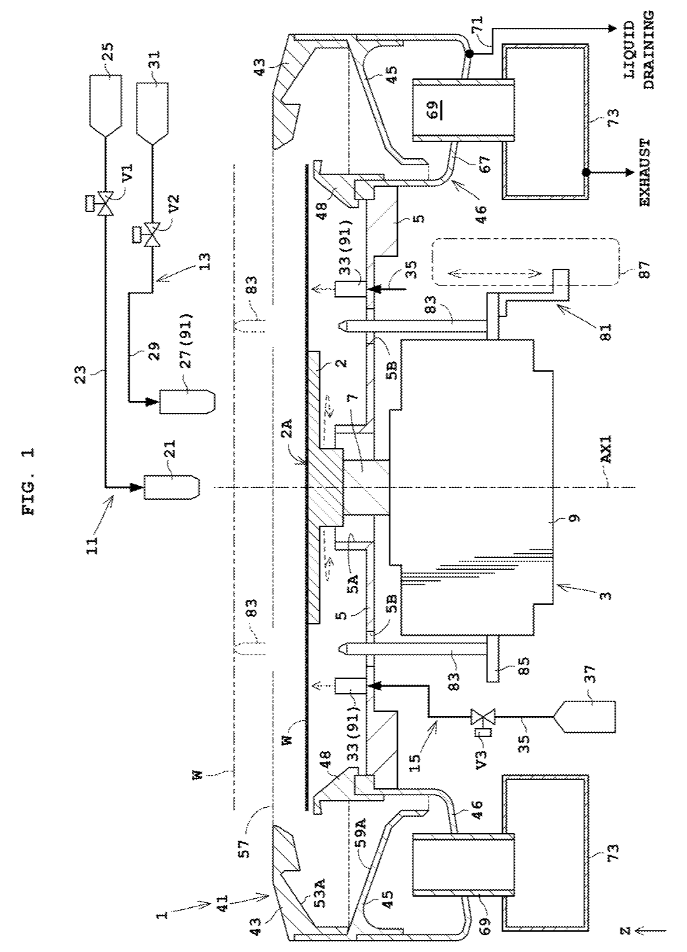

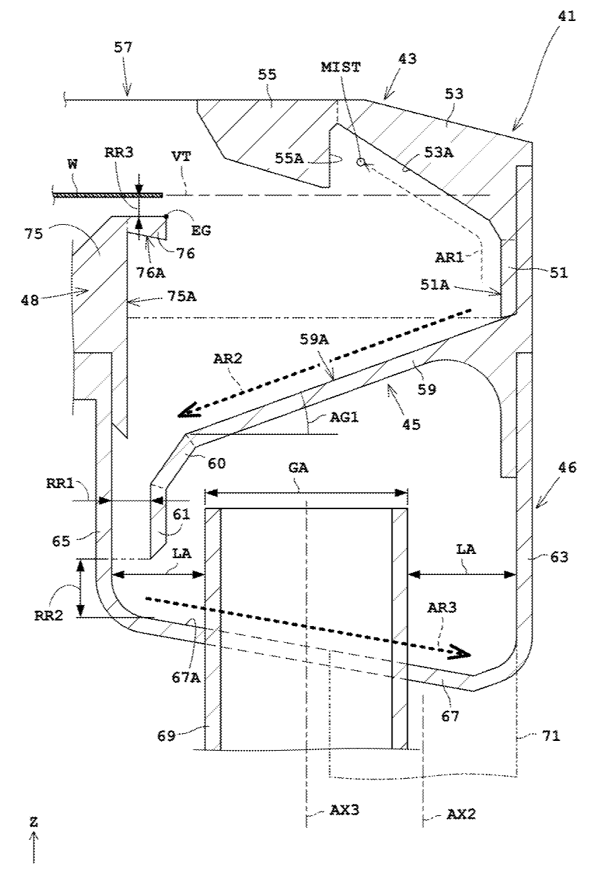

Hereinafter, a first embodiment of the present invention will be described with reference to the drawings. FIG. 1 is a longitudinal sectional view showing a substrate processing apparatus 1 according to the first embodiment. FIG. 2 is an enlarged longitudinal sectional view of a right portion of a cup 41 shown in FIG. 1. In the present embodiment, a horizontal direction is a direction orthogonal to a vertical direction Z.

### 1. Basic configuration of substrate processing apparatus

Reference is made to FIG. 1. The substrate processing apparatus 1 applies a coating liquid to a substrate W. The substrate processing apparatus 1 includes a spin chuck 2, a rotation mechanism 3, and a support plate 5. The substrate W is formed in, for example, a disk shape.

The spin chuck 2 holds the substrate W in a horizontal posture. The spin chuck 2 is, for example, a vacuum chuck. The vacuum chuck is configured to hold a central portion of a lower surface of the substrate W by vacuum suction by a pump. When the spin chuck 2 is the vacuum chuck, a diameter of an upper surface 2A (holding surface) of the spin chuck 2 is smaller than a diameter of the substrate W. The spin chuck 2 is not limited to the vacuum chuck, and may be, for example, a mechanical chuck. The mechanical chuck includes a disk-shaped spin base and at least three holding pins provided on an upper surface of the spin base. The mechanical chuck grips a side surface of the substrate W in the horizontal posture with the at least three holding pins.

The rotation mechanism 3 rotates the spin chuck 2 about a vertical axis AX1. The vertical axis AX1 passes through the center of the substrate W held by the spin chuck 2. The rotation mechanism 3 includes a rotation shaft 7 and an electric motor 9. An upper end of the rotation shaft 7 is fixed to a lower end of the spin chuck 2. The rotation shaft 7 extends in a vertical downward direction from the spin chuck 2. An output rotation shaft of the electric motor 9 is connected to a lower portion of the rotation shaft 7. The electric motor 9 rotates the spin chuck 2 about the vertical axis AX1 via the rotation shaft 7.

The support plate 5 is formed in a disk shape. The support plate 5 is disposed between the spin chuck 2 and the rotation mechanism 3 in the vertical direction Z. A passing hole 5A is provided in a central portion of the support plate 5, and the rotation shaft 7 passes through the passing hole 5A. Further, the support plate 5 is provided with three pin passing holes 5B through which three support pins 83 to be described later respectively pass. The support plate 5 is fixed. That is, the support plate 5 is not rotated unlike the spin chuck 2, and is neither horizontally moved nor lifted and lowered.

### 1-1. Treatment liquid supply mechanism

The substrate processing apparatus 1 includes a coating liquid supply mechanism 11, a first solvent supply mechanism 13, and a second solvent supply mechanism 15. The coating liquid supply mechanism 11 supplies the coating liquid to an upper surface of the substrate W in order to perform a coating treatment. The first solvent supply mechanism 13 supplies a solvent to the upper surface of the substrate W in order to perform a pre-wet treatment. Then, the second solvent supply mechanism 15 supplies a solvent to the lower surface of the substrate W in order to perform a back-rinse treatment.

The coating liquid supply mechanism 11 includes a coating liquid nozzle 21, a coating liquid pipe 23, an on-off valve V1, and a first pump (not shown). The coating liquid nozzle 21 discharges the coating liquid to the upper surface of the substrate W held by the spin chuck 2. As the coating liquid, for example, a resist liquid is used. The coating liquid may be liquid other than the resist liquid (for example, liquid for forming a film such as an antireflection film). A viscosity of the coating liquid may be high or low.

The coating liquid nozzle 21 is moved to an arbitrary position such as a discharge position above the center of the substrate W held by the spin chuck 2 by a nozzle moving mechanism (not shown). One end of the coating liquid pipe 23 is connected to the coating liquid nozzle 21. The other end of the coating liquid pipe 23 is connected to a coating liquid supply source 25. The on-off valve V1 and the first pump are provided in the coating liquid pipe 23. The first pump sends the coating liquid in the coating liquid supply source 25 to the coating liquid nozzle 21 through the coating liquid pipe 23. The on-off valve V1 selectively supplies the coating liquid and stops the supply of the coating liquid.

The first solvent supply mechanism 13 includes a solvent nozzle 27, a solvent pipe 29, an on-off valve V2, and a second pump (not shown). The solvent nozzle 27 discharges the solvent to the upper surface of the substrate W held by the spin chuck 2. As the solvent (organic solvent), for example, thinner, propylene glycol monomethyl ether acetate (PGMEA), N-methyl-2-pyrrolidone (NMP), or cyclopentanone is used.

The solvent nozzle 27 is moved to an arbitrary position such as a discharge position above the center of the substrate W held by the spin chuck 2 by the nozzle moving mechanism (not shown). One end of the solvent pipe 29 is connected to the solvent nozzle 27. The other end of the solvent pipe 29 is connected to a first solvent supply source 31. The on-off valve V2 and the second pump are provided in the solvent pipe 29. The second pump sends the solvent in the first solvent supply source 31 to the solvent nozzle 27 through the solvent pipe 29. The on-off valve V2 selectively supplies the solvent and stops the supply of the solvent.

The second solvent supply mechanism 15 includes two solvent nozzles 33, a solvent pipe 35, an on-off valve V3, and a third pump (not shown). The two solvent nozzles 33 discharge the solvents to the lower surface of the substrate W held by the spin chuck 2. The two solvent nozzles 33 are provided on an upper surface of the support plate 5. The two solvent nozzles 33 are disposed below the substrate W held by the spin chuck 2.

The solvent pipe 35 is connected to each of the two solvent nozzles 33. A base end of the solvent pipe 35 is connected to a second solvent supply source 37. The on-off valve V3 and the third pump are provided in the solvent pipe 35. The third pump sends the solvent in the second solvent supply source 37 to each solvent nozzle 33 through the solvent pipe 35. The on-off valve V3 selectively supplies the solvent and stops the supply of the solvent. The number of the solvent nozzles 33 may be at least one.

### 1-2. Cup

The substrate processing apparatus 1 includes the cup 41. The cup 41 accommodates the spin chuck 2 and the substrate W held by the spin chuck 2. The cup 41 recovers the coating liquid and the solvent scattered from the substrate W held by the spin chuck 2. As shown in FIG. 1, the cup 41 is attached to an outer peripheral end of the support plate 5. Therefore, the cup 41 is not rotated unlike the spin chuck 2, and is neither horizontally moved nor lifted and lowered. That is, the cup 41 is fixed in position so as not to lift and lower with respect to the spin chuck 2.

Reference is made to FIGS. 1 and 2. The cup 41 includes an upper cup 43, a middle cup 45, a lower cup 46, and an inner cup 48. The upper cup 43 is provided so as to surround a side of the substrate W held by the spin chuck 2. The upper cup 43 is formed in a cylindrical shape. A central axis extending in the vertical direction Z of the cylindrical upper cup 43 coincides with the vertical axis AX1. An upper portion of the upper cup 43 projects in an inward direction toward an inner peripheral side, that is, the vertical axis AX1. The upper cup 43, the middle cup 45, the lower cup 46, and the inner cup 48 are concentrically formed in plan view.

### 1-2-1. Upper cup

The upper cup 43 includes an outer peripheral wall 51, a ceiling wall 53 (having a trap portion 55), and an upper opening 57. The upper opening 57 is disposed in an upper portion and a central portion of the upper cup 43. The upper opening 57 is formed by an inner peripheral end of the trap portion 55. The upper opening 57 is formed in a size that allows the substrate W in the horizontal posture to pass therethrough. The outer peripheral wall 51 is formed in a cylindrical shape. The outer peripheral wall 51 has an inner side surface 51A (side surface) of the outer peripheral wall 51. The side surface 51A extends in a cylindrical shape in the vertical direction Z.

The ceiling wall 53 is formed in a ring shape while extending in the inward direction toward the vertical axis AX1 from an upper portion of the outer peripheral wall 51. Specifically, the ceiling wall 53 is formed in a ring shape while extending in an obliquely upward direction from the upper portion of the outer peripheral wall 51 in the inward direction. The ceiling wall 53 has a liquid receiving surface 53A (side surface) on an inner side of the ceiling wall 53. The liquid receiving surface 53A is a surface that receives the liquid scattered from the substrate W held by the spin chuck 2.

The liquid receiving surface 53A is formed like a side surface of a truncated cone. In other words, the liquid receiving surface 53A is formed in a cylindrical shape while extending in the obliquely upward direction from an upper end portion of the side surface 51A of the outer peripheral wall 51 toward the vertical axis AX1. Therefore, the liquid receiving surface 53A is directed in the inward direction and in an obliquely downward direction. In addition, the liquid receiving surface 53A is formed so as to intersect with a virtual line VT (or virtual plane) extending outward in a radius direction of the substrate W from an outer peripheral end of the substrate W held by the spin chuck 2. The virtual line VT extends in the horizontal direction.

As a result, the liquid scattered from the substrate W held by the spin chuck 2 can be bounced in a downward direction. Therefore, it is possible to suppress the liquid scattered from the substrate W from bouncing back on the liquid receiving surface 53A and the bounced liquid from adhering again to the substrate W.

The trap portion 55 suppresses a mist of at least one of the coating liquid and the solvent scattered from the substrate W held by the spin chuck 2 from adhering again to the substrate W held by the spin chuck 2. The trap portion 55 is formed in a ring shape in an inner peripheral portion of the ceiling wall 53 and protrudes in the downward direction from an inner surface (liquid receiving surface 53A) of the ceiling wall 53. A trap surface 55A is formed on an outer peripheral side of the trap portion 55. That is, the trap portion 55 has the trap surface 55A formed in a cylindrical shape while extending in the vertical direction Z. The trap surface 55A is a surface of the trap portion 55 on the outer peripheral wall 51 side. The trap surface 55A faces the outer peripheral wall 51 in plan view.

A lower end of the trap portion 55 is located at a position higher than the virtual line VT so that the coating liquid and the solvent scattered from the substrate W held by the spin chuck 2 hit the liquid receiving surface 53A. In FIG. 2, the lower end of the trap portion 55 is also a lower end of the trap surface 55A.

The side surface 51A, the liquid receiving surface 53A, and the trap surface 55A are configured as follows. As shown in FIG. 2, an upper end portion of the trap surface 55A is connected to an upper end portion of the liquid receiving surface 53A. A lower end portion of the liquid receiving surface 53A is connected to the upper end portion of the side surface 51A. As described above, the trap surface 55A is formed to extend in a cylindrical shape in the vertical direction Z. Therefore, the trap surface 55A can more effectively capture a mist flowing from the side surface 51A side along the liquid receiving surface 53A as indicated by an arrow AR1. As a result, it is possible to suppress the liquid from adhering again to the substrate W held by the spin chuck 2.

In the present embodiment, the ceiling wall 53 has the liquid receiving surface 53A. In this regard, the ceiling wall 53 may not have the liquid receiving surface 53A. In this case, the outer peripheral wall 51 may have not only the side surface 51A but also the liquid receiving surface 53A. The outer peripheral wall 51 and the ceiling wall 53 may share the liquid receiving surface 53A.

### 1-2-2. Middle cup

First, an outline of the middle cup 45 will be described. The middle cup 45 is disposed in a ring shape between the upper cup 43 and the lower cup 46 so as to cover an upper side of an exhaust area GA of the lower cup 46. The middle cup 45 cover the exhaust area GA in plan view. The middle cup 45 is inclined downward from its outer peripheral end portion toward its inner peripheral end portion. The middle cup 45 can receive the coating liquid and the solvent that have flowed down along an inner surface (for example, the liquid receiving surface 53A and the side surface 51A) of the upper cup 43 on the outer peripheral end portion side. The middle cup 45 causes the received coating liquid and solvent to flow downward to the inner peripheral end portion side of the middle cup 45 to be guided to a drainage area LA of the lower cup 46.

Next, details of the middle cup 45 will be described. The outer peripheral end portion of the middle cup 45 is coupled to the inner surface (for example, the side surface 51A) of the upper cup 43. In other words, the middle cup 45 is provided on a side wall of the upper cup 43. In FIG. 2, the middle cup 45 is provided on the outer peripheral wall 51 of the upper cup 43.

The middle cup 45 is formed in a ring shape. The middle cup 45 is inclined in the downward direction from the outer peripheral wall 51 toward the vertical axis AX1 and the rotation shaft 7. A base end portion of the middle cup 45 on the outer peripheral wall 51 side is not provided with a hole penetrating from an upper surface 59A of the middle cup 45 to a lower surface of the middle cup 45. As a result, the middle cup 45 can cause all of the coating liquid and all of the solvent scattered from the substrate W held by the spin chuck 2 to flow in a direction from the outer peripheral wall 51 toward the vertical axis AX1 (arrow AR2). The middle cup 45 is disposed at a position lower than the virtual line VT shown in FIG. 2. As a result, it is possible to suppress the liquid received by the upper surface 59A of the middle cup 45 from bouncing upward, and the bounced liquid from adhering again to the substrate W.

The middle cup 45 includes a middle cup body 59, an intermediate member 60, and a distal end member 61. A base end of the middle cup body 59 is provided on the outer peripheral wall 51. The middle cup body 59 is formed in a ring shape while extending in the obliquely downward direction toward the vertical axis AX1. As shown in FIG. 2, an angle AG1 of the middle cup body 59 with respect to the horizontal direction is, for example, 20 degrees.

The intermediate member 60 is provided at a distal end of the middle cup body 59. The intermediate member 60 is formed in a cylindrical shape while extending in the obliquely downward direction toward the vertical axis AX1. An angle of the intermediate member 60 with respect to the horizontal direction is larger than the angle AG1 (for example, 20 degrees) of the middle cup body 59 and less than 90 degrees. The distal end member 61 is provided at a distal end of the intermediate member 60. The distal end member 61 is formed in a cylindrical shape so as to extend in the vertical direction Z. Note that the intermediate member 60 may not be provided, and the distal end member 61 may be directly provided at the distal end of the middle cup body 59. A configuration of the middle cup 45 related to the lower cup 46 will be described later.

### 1-2-3. Lower cup

The lower cup 46 is provided below the upper cup 43. The lower cup 46 is a ring-shaped container having a bottom wall 67. The lower cup 46 accommodates the coating liquid and the solvent flowing down from the middle cup 45. The lower cup 46 has the drainage area LA and the exhaust area GA. In the lower cup 46, the drainage area LA and the exhaust area GA are provided separately in the container.

The lower cup 46 includes an outer peripheral wall 63, an inner peripheral wall 65, the bottom wall 67, two exhaust pipes 69, and a drain 71. The number of each of the exhaust pipes 69 and the drains 71 may be at least one.

The outer peripheral wall 63 and the inner peripheral wall 65 are formed in a cylindrical shape. The outer peripheral wall 63 extends in a vertical upward direction from an outer peripheral end of the bottom wall 67. An upper end of the outer peripheral wall 63 is connected to or adjacent to a lower end of the outer peripheral wall 51 of the upper cup 43. The inner peripheral wall 65 is disposed between the spin chuck 2 and the outer peripheral wall 63 in the horizontal direction. The inner peripheral wall 65 extends in the vertical upward direction from an inner peripheral end of the bottom wall 67. The bottom wall 67 is formed in a ring shape, and connects a lower portion of the outer peripheral wall 63 and a lower portion of the inner peripheral wall 65. The bottom wall 67 is inclined in the downward direction from the inner peripheral wall 65 toward the outer peripheral wall 63. Therefore, the coating liquid and the solvent that have flowed down on a bottom surface 67A (upper surface) on an inner side of the bottom wall 67 flow in a direction from the inner peripheral wall 65 toward the outer peripheral wall 63 (arrow AR3).

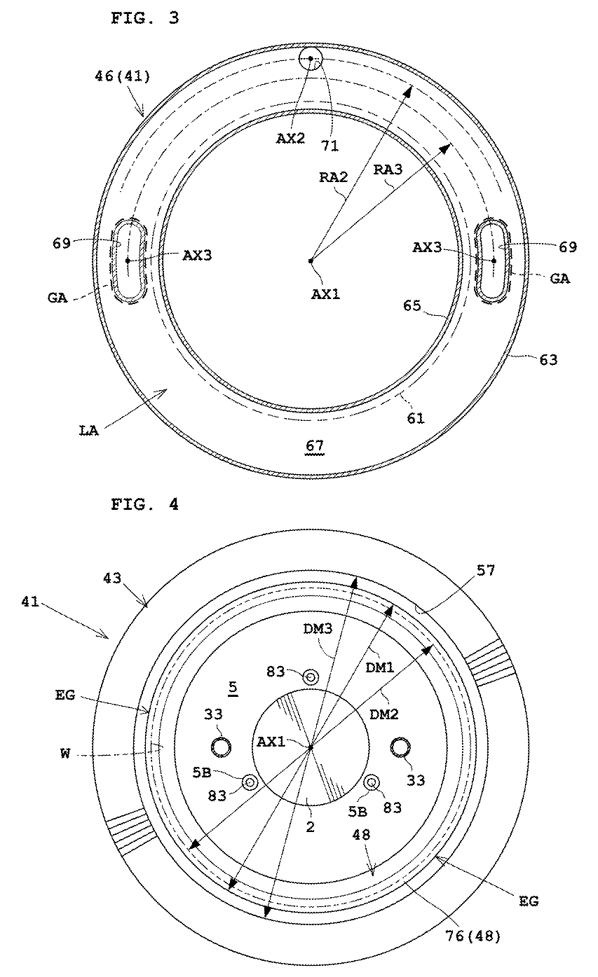

Each of the two exhaust pipes 69 and the drain 71 is provided on the bottom wall 67. Specifically, the two exhaust pipes 69 are provided on the bottom wall 67 in the exhaust area GA. In the present embodiment, as shown in FIG. 3, the exhaust area GA is a region where the two exhaust pipes 69 are provided. In the present embodiment, the drainage area LA is a region other than the exhaust area GA in which the two exhaust pipes 69 are provided, in a region surrounded by the outer peripheral wall 63 and the inner peripheral wall 65.

As shown in FIGS. 2 and 3, each of the two exhaust pipes 69 is disposed substantially at the center between the outer peripheral wall 63 and the inner peripheral wall 65 of the lower cup 46. The two exhaust pipes 69 are disposed at equal intervals (180 degree intervals) around the spin chuck 2 and the vertical axis AX1. The drain 71 is formed in a tubular shape, for example. The drain 71 is connected to a drainage facility of a factory.

The drain 71 is disposed on an outer peripheral side of the two exhaust pipes 69. Specifically, a central axis AX2 extending in the vertical direction Z of the drain 71 is disposed on an outer peripheral side of a central axis AX3 extending in the vertical direction Z of each exhaust pipe 69. In other words, as shown in FIG. 3, a radius RA2 between the vertical axis AX1 and the central axis AX2 is longer than a radius RA3 between the vertical axis AX1 and the central axis AX3. By disposing the two exhaust pipes 69 and the drain 71 in this manner, the lower cup 46 having the same shape as a lower cup of a developing device that performs development processing can be used. Since a common component (lower cup) can be used, the cost of the substrate processing apparatus 1 can be reduced.

As shown in FIG. 2, an upper end of each exhaust pipe 69 is located at a position higher than the bottom surface 67A and at a position lower than the middle cup body 59. This suppresses the coating liquid and the solvent that have flowed down on the bottom surface 67A from flowing into each exhaust pipe 69. The upper end of each exhaust pipe 69 is preferably located at a position higher than a lower end of the distal end member 61 of the middle cup 45. The coating liquid and the solvent are further suppressed from flowing into each exhaust pipe 69.

Lower ends of the two exhaust pipes 69 are each connected to a single exhaust box 73. The exhaust box 73 is formed in, for example, a U shape in plan view. The exhaust box 73 is connected to an exhaust facility (for example, having a pump) of a factory and is exhausted at a preset flow rate. Therefore, gas in the cup 41 is sucked from the two exhaust pipes 69. That is, the two exhaust pipes 69 are configured to exhaust gas that has flowed in from the upper opening 57 of the upper cup 43 and passed between an inner peripheral end of the middle cup 45 and the inner peripheral wall 65 of the lower cup 46.

Here, a configuration of the middle cup 45 related to the lower cup 46 will be described. A base end of the middle cup 45 is provided on the outer peripheral wall 63 of the lower cup 46 (and the outer peripheral wall 51 of the upper cup 43). The middle cup 45 is formed to extend in the obliquely downward direction toward the vertical axis AX1 while covering the two exhaust pipes 69. Therefore, the middle cup 45 is accommodated in the lower cup 46.

A flow path RR1 for causing the coating liquid, the solvent, and the gas to flow is formed between the distal end member 61 of the middle cup 45 and the inner peripheral wall 65. In other words, the middle cup 45 forms the gap (flow path RR1) between the inner peripheral end portion of the middle cup 45 and the inner peripheral wall 65 of the lower cup 46. The gap between the inner peripheral end portion of the middle cup 45 and the inner peripheral wall 65 of the lower cup 46 can guide the coating liquid and the solvent to the drainage area LA and can guide the gas to the exhaust area GA.

The gap (flow path RR1) is located below the outer peripheral end of the substrate W. Since the gas flows in a relatively vertical downward direction to the gap between the inner peripheral end portion of the middle cup 45 and the inner peripheral wall 65 of the lower cup 46 from near the outer peripheral end of the substrate W, for example, the gas including a mist of the coating liquid can be caused to flow smoothly.

The distal end member 61 of the middle cup 45 extends in the vertical downward direction along the inner peripheral wall 65 of the lower cup 46 to be described later. In other words, the middle cup 45 forms the gap (flow path RR1) extending in the downward direction with the inner peripheral wall 65 of the lower cup 46 as a distal end of the inner peripheral end portion of the middle cup 45 hangs down in the vertical downward direction. Since the gap extends in the downward direction between the inner peripheral end portion of the middle cup 45 and the inner peripheral wall 65 of the lower cup, it is possible to suppress turbulence of airflow passing through the gap.

A flow path RR2 through which the coating liquid, the solvent, and the gas flow is formed between the distal end member 61 and the bottom wall 67. In addition, the distal end member 61 is disposed on an inner peripheral side of the center between the outer peripheral wall 63 and the inner peripheral wall 65 of the lower cup 46, in the horizontal direction. As a result, a space in the flow path RR1 is reduced, and a flow velocity (m/s) of the gas passing through the flow path RR1 can be increased. Further, the distal end member 61 is disposed on an inner peripheral side of inner peripheral ends of the two exhaust pipes 69 in the horizontal direction. As a result, upper sides of the two exhaust pipes 69 can be further covered with the middle cup 45, whereby the coating liquid and the solvent can be suppressed from flowing into each exhaust pipe 69.

### 1-2-4. Inner cup

The inner cup 48 extends in a cylindrical shape in the vertical upward direction from an upper end of the inner peripheral wall 65 of the lower cup 46 toward the lower surface of the substrate W held by the spin chuck 2. An upper end of the inner cup 48 is positioned near the lower surface of the substrate W held by the spin chuck 2. A flow path RR3 is formed between the upper end of the inner cup 48 and the lower surface of the substrate W held by the spin chuck 2. The solvent flowing to the lower surface of the substrate W is passed through the flow path RR3 during the back-rinse treatment.

The inner cup 48 is formed in a cylindrical shape. The inner cup 48 includes an inner cup body 75 and a flow straightening member 76. The inner cup body 75 is formed in a cylindrical shape. The inner cup body 75 has an outer peripheral surface 75A on an outer side of the inner cup body 75. The flow straightening member 76 is formed in a ring shape at an upper end portion of the inner cup body 75.

An outer peripheral end EG of the flow straightening member 76 protrudes toward an outer peripheral side more than the outer peripheral surface 75A. As a result, the flow straightening member 76 (for example, a lower surface 76A of an outer peripheral portion of the flow straightening member 76) suppresses the coating liquid and the solvent from adhering to the lower surface of the substrate W held by the spin chuck 2.

In addition, as shown in FIG. 2, the outer peripheral end EG of the flow straightening member 76 preferably protrudes toward an outer peripheral side more than the outer peripheral end of the substrate W held by the spin chuck 2. That is, as shown in FIG. 4, the flow straightening member 76 is configured such that a diameter DM1 of the outer peripheral end EG of the flow straightening member 76 (that is, the inner cup 48) is larger than a diameter DM2 of the substrate W held by the spin chuck 2 (diameter DM1 > diameter DM2). The diameter DM1 of the outer peripheral end EG of the flow straightening member 76 is preferably smaller than a diameter DM3 of the upper opening 57 (diameter DM3 > diameter DM1).

### 1-3. Substrate lifting and lowering mechanism

In the substrate processing apparatus 1 of the present embodiment, the cup 41 does not move in the vertical direction Z with respect to the spin chuck 2. That is, the cup 41 (for example, the upper cup 43 and the middle cup 45) is fixed in position so as not to lift and lower with respect to the spin chuck 2. Therefore, the substrate processing apparatus 1 of the present embodiment includes a substrate lifting and lowering mechanism 81 that lifts and lowers the substrate W in order to transfer the substrate W. As shown in FIGS. 1 and 5, the substrate lifting and lowering mechanism 81 includes at least three (for example, three) support pins 83, a base member 85, and a lifting and lowering mechanism 87.

The three support pins 83 support the substrate W. The substrate W is placed on three distal ends of the three support pins 83. The at least three support pins 83 are provided at equal angular intervals (for example, 120 degree intervals) around the vertical axis AX1. The three support pins 83 are disposed on an outer peripheral side of the spin chuck 2 and on an inner peripheral side of the upper cup 43 and the inner cup 48 in the horizontal direction. The three support pins 83 are attached to an upper surface of the base member 85. The base member 85 is formed in a C shape or a ring shape in plan view.

The lifting and lowering mechanism 87 lifts and lowers the three support pins 83 that support the substrate W via the base member 85. In addition, the lifting and lowering mechanism 87 lifts and lowers the three support pins 83 between a standby position H1, a holding position H2, and a transfer position H3. The transfer position H3 is higher than the holding position H2, and the holding position H2 is higher than the standby position H1 (transfer position H3 > holding position H2 > standby position H1). Therefore, the lifting and lowering mechanism 87 lifts and lowers the substrate W between the holding position H2 of the upper surface of the spin chuck 2 and the transfer position H3 higher than the upper end of the upper cup 43, through the upper opening 57. The lifting and lowering mechanism 87 includes, for example, two pulleys 87A and 87B, a belt 87C, a slider 87D, and an electric motor 87E.

The two pulleys 87A and 87B are disposed in the vertical direction Z. The belt 87C is wound around the two pulleys 87A and 87B. The slider 87D is fixed to the belt 87C, and the base member 85 is attached to the slider 87D. An output rotation shaft of the electric motor 87E is connected to, for example, the pulley 87A. When the electric motor 87E positively rotates the output rotation shaft, the three support pins 83, the base member 85, and the slider 87D lift. On the other hand, when the electric motor 87E reversely rotates the output rotation shaft, the three support pins 83 and the like lower. Instead of these configurations, the lifting and lowering mechanism 87 may include an air cylinder or an actuator having an electric motor and a screw shaft.

According to the substrate lifting and lowering mechanism 81, the substrate W can be placed on the upper surface of the spin chuck 2 accommodated in the upper cup 43 through the upper opening 57 of the upper cup 43, and the substrate W on the upper surface of the spin chuck 2 can be taken out from the upper cup 43 through the upper opening 57 of the upper cup 43.

### 1-4. Solvent scattering mechanism

The substrate processing apparatus 1 includes a solvent scattering mechanism 91. The solvent scattering mechanism 91 scatters the solvent toward an outside in a rotation radius direction of the spin chuck 2 in cooperation with the rotation mechanism 3. In other words, the solvent scattering mechanism 91 scatters the solvent toward an inner side surface of the upper cup 43 (for example, the liquid receiving surface 53A) in cooperation with the rotation mechanism 3. The solvent scattering mechanism 91 may scatter the solvent to the side surface 51A of the outer peripheral wall 51. In the present embodiment, the solvent scattering mechanism 91 includes at least one of the two solvent nozzles 27 and 33. The solvent scattering mechanism 91 may include the substrate W held by the spin chuck 2.

For example, the solvent nozzle 27 discharges the solvent to the upper surface of the substrate W held by the spin chuck 2. In addition, the rotation mechanism 3 rotates the substrate W held by the spin chuck 2 about the vertical axis AX1. As a result, the solvent discharged to the upper surface of the substrate W is scattered to the liquid receiving surface 53A on the inner side of the upper cup 43.

The solvent nozzle 33 discharges the solvent to the lower surface of the substrate W held by the spin chuck 2. In addition, the rotation mechanism 3 rotates the substrate W held by the spin chuck 2 about the vertical axis AX1. As a result, the solvent discharged to the lower surface of the substrate W is scattered to the liquid receiving surface 53A on the inner side of the upper cup 43.

### 1-5. Configuration related to control

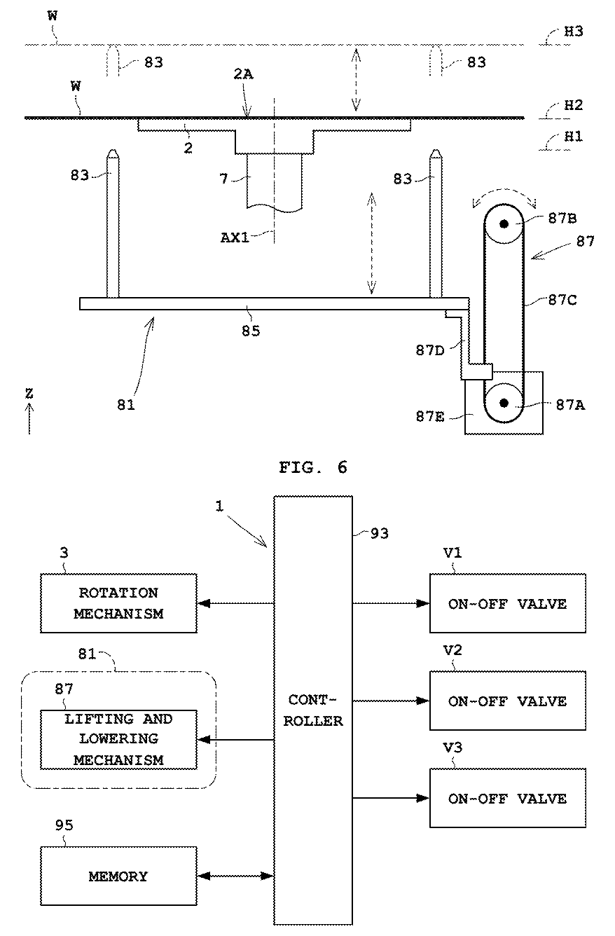

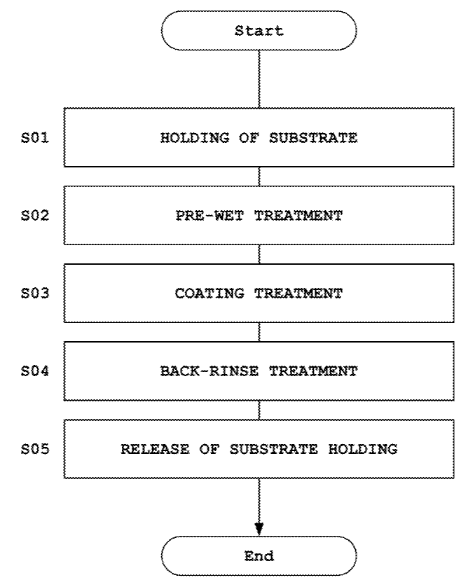

Reference is made to FIG. 6. The substrate processing apparatus 1 includes a controller 93 and a memory 95. The controller 93 controls each component of the substrate processing apparatus 1. The controller 93 controls, for example, the rotation mechanism 3, the three on-off valves V1, V2, and V3, and the substrate lifting and lowering mechanism 81. The controller 93 includes one or more processors such as, for example, a central processing unit (CPU). The memory 95 is also referred to as a storage medium. The memory 95 includes, for example, at least one of a read-only memory (ROM), a random-access memory (RAM), and a hard disk. The memory 95 stores a computer program and a parameter necessary for controlling each component of the substrate processing apparatus 1. The controller 93 reads necessary information (for example, the parameter) from the memory 95.

The spin chuck 2 corresponds to each of a chuck and a substrate holding unit of the present invention. Each of the solvent nozzle 27 and the solvent nozzle 33 corresponds to a first solvent nozzle of the present invention. At least one of the side surface 51A and the liquid receiving surface 53A corresponds to an inner side surface of the present invention. The lifting and lowering mechanism 87 corresponds to a support pin lifting and lowering mechanism of the present invention.

### 2. Operation of substrate processing apparatus

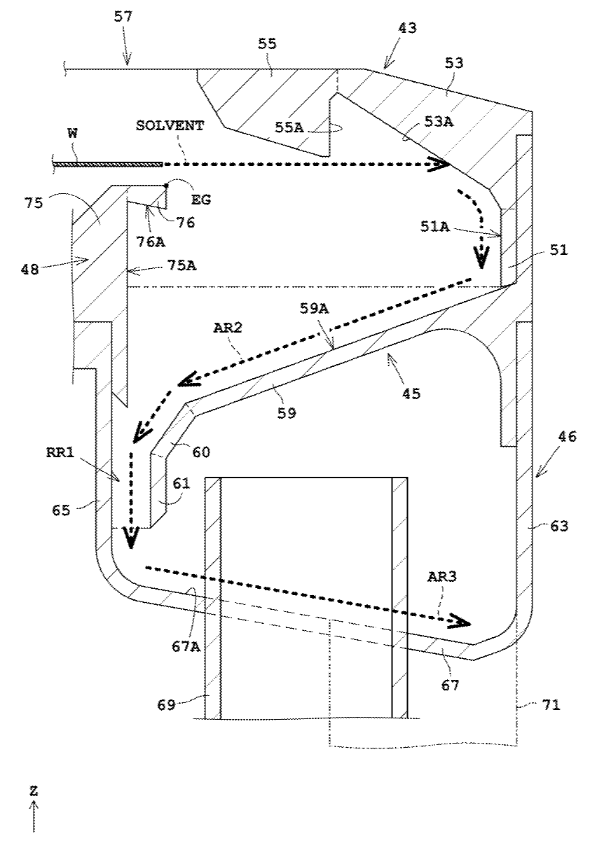

Next, an operation of the substrate processing apparatus 1 will be described with reference to a flowchart of FIG. 7. First, a substrate transfer robot (not shown) moves a hand holding the substrate W in the horizontal posture above the spin chuck 2.

### Step S01 Holding of substrate

Thereafter, the lifting and lowering mechanism 87 of the substrate lifting and lowering mechanism 81 lifts the three support pins 83 from the standby position H1 to the transfer position H3. As a result, the three support pins 83 lift the substrate W from the hand of the substrate transfer robot. That is, the three support pins 83 receive the substrate W from the substrate transfer robot. Thereafter, the substrate transfer robot moves the hand not holding the substrate W from above the spin chuck 2.

Thereafter, the lifting and lowering mechanism 87 lowers the three support pins 83 that support the substrate W in the horizontal posture from the transfer position H3 to the standby position H1. During this lowering, at the holding position H2, the substrate W is placed on the upper surface of the spin chuck 2, and the three support pins 83 are separated from the lower surface of the substrate W. Thereafter, the spin chuck 2 holds the substrate W in the horizontal posture by vacuum suction.

### Step S02 Pre-wet treatment

The pre-wet treatment is a treatment performed in order to easily spread the coating liquid on the upper surface of the substrate W in the coating treatment in step S03. The solvent nozzle 27 shown in FIG. 1 is moved above the center of the substrate W held by the spin chuck 2 by the nozzle moving mechanism (not shown).

Thereafter, the controller 93 opens the on-off valve V2 to discharge the solvent from the solvent nozzle 27 to the upper surface of the substrate W held by the spin chuck 2. Further, the controller 93 controls the rotation mechanism 3 to rotate the substrate W held by the spin chuck 2 about the vertical axis AX1 at preset revolutions per minute (rpm). As a result, the solvent discharged to the upper surface of the substrate W is spread over the entire upper surface of the substrate W by the rotation of the substrate W. That is, a liquid film of the solvent is formed on the upper surface of the substrate W.

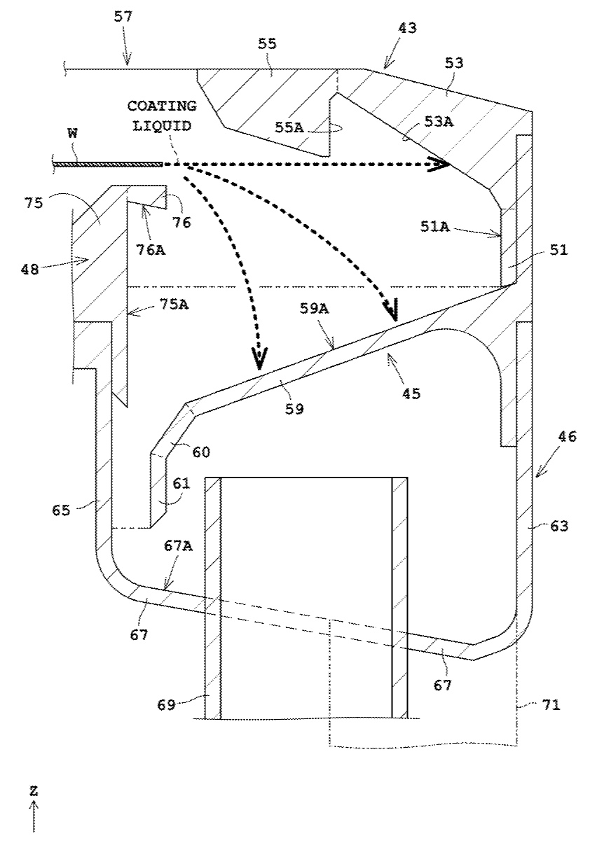

In addition, the excess solvent on the upper surface of the substrate W is scattered from the substrate W by a centrifugal force due to the rotation of the substrate W. As shown in FIG. 8, the solvent is scattered in the substantially horizontal direction from the rotated substrate W. The solvent scattered in the substantially horizontal direction hits the liquid receiving surface 53A of the upper cup 43 and flows down to the base end portion of the middle cup 45, that is, the upper surface 59A of the middle cup 45 on an outer peripheral end side. Thereafter, the solvent flows on the upper surface 59A of the middle cup 45 from the outer peripheral end side of the middle cup 45 toward the distal end member 61.

Here, the middle cup 45 is provided on the outer peripheral wall 51 of the upper cup 43 and is formed to extend in the obliquely downward direction from the outer peripheral wall 51 toward the vertical axis AX1. Therefore, the solvent can be caused to flow from the outer peripheral end side of the middle cup 45 toward the distal end member 61. Therefore, every time the pre-wet treatment is performed on the substrate W, the solvent can be caused to flow to substantially the entire upper surface 59A of the middle cup 45. As a result, drying of the coating liquid adhering to the upper surface 59A of the middle cup 45 can be suppressed, and the coating liquid can be easily washed off to the lower cup 46.

Thereafter, the solvent flows down from the upper surface 59A of the middle cup 45 to the bottom surface 67A of the lower cup 46 while passing through the flow path RR1 between the inner peripheral wall 65 of the lower cup 46 and the distal end member 61. Thereafter, the solvent is drained from the bottom surface 67A to the drain 71.

After a preset amount of the solvent is discharged from the solvent nozzle 27, the on-off valve V2 is closed to stop the discharge of the solvent from the solvent nozzle 27. Thereafter, the rotation mechanism 3 stops the rotation of the substrate W held by the spin chuck 2. In this regard, the rotation mechanism 3 may continue the rotation of the substrate W at preset revolutions per minute.

### Step S03 Coating treatment

After the pre-wet treatment (step S02) on the substrate W is completed, for example, the nozzle moving mechanism (not shown) moves the coating liquid nozzle 21 above the center of the substrate W held by the spin chuck 2. By opening the on-off valve V1, the coating liquid nozzle 21 discharges the coating liquid to the upper surface of the substrate W held by the spin chuck 2. In addition, the rotation mechanism 3 rotates the substrate W held by the spin chuck 2 about the vertical axis AX1 at preset revolutions per minute. As a result, the coating liquid discharged to the upper surface of the substrate W is spread over the entire upper surface of the substrate W by the rotation of the substrate W while replacing the liquid film of the solvent formed on the upper surface of the substrate W with the coating liquid. That is, a coating liquid film is formed on the upper surface of the substrate W.

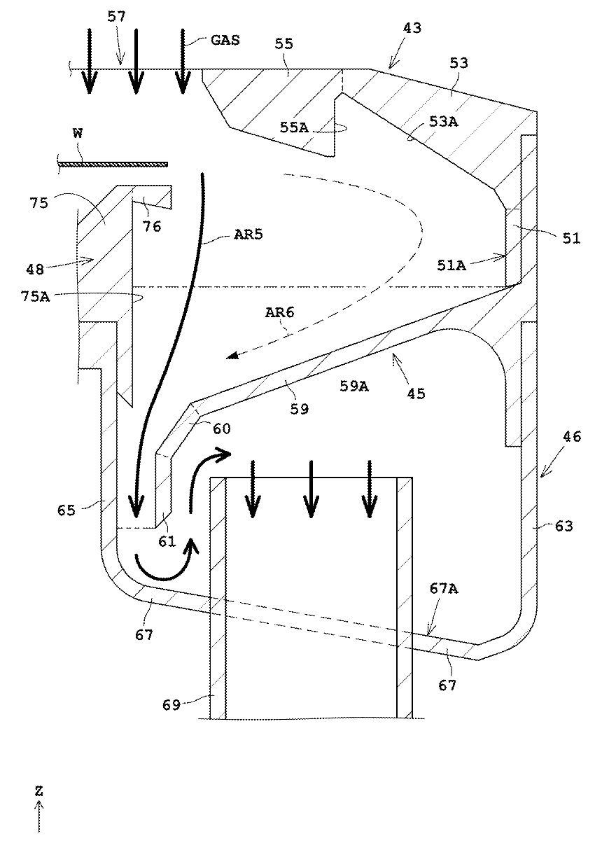

The excess coating liquid on the upper surface of the substrate W is scattered from the substrate W by the rotation of the substrate W. In FIG. 9, for example, when the revolutions per minute of the substrate W are relatively low as in the initial stage of the coating treatment, the coating liquid is scattered from the substrate W so as to draw a parabola. Therefore, the coating liquid is scattered to the upper surface 59A of the middle cup 45 and adheres to the upper surface 59A. When the revolutions per minute of the substrate W are relatively large, the coating liquid is scattered from the substrate W in the substantially horizontal direction. When the coating liquid flows, the coating liquid flows toward the drain 71 similarly to the solvent.

After a preset amount of the coating liquid is discharged from the coating liquid nozzle 21, the on-off valve V1 is closed to stop the discharge of the coating liquid from the coating liquid nozzle 21. Thereafter, the rotation mechanism 3 stops the rotation of the substrate W held by the spin chuck 2. In this regard, the rotation mechanism 3 may continue the rotation of the substrate W at preset revolutions per minute.

### Step S04 Back-rinse treatment

The back-rinse treatment is a treatment for cleaning the lower surface of the substrate W in order to suppress transfer of the coating liquid adhering to the lower surface of the substrate W to, for example, the hand of the substrate transfer robot (not shown). The solvent nozzles 33 shown in FIG. 1 are disposed below the substrate W held by the spin chuck 2.

After the coating treatment (step S03) on the substrate W is completed, the rotation mechanism 3 rotates the substrate W held by the spin chuck 2 about the vertical axis AX1 at preset revolutions per minute. Thereafter, by opening the on-off valve V3, the solvent is discharged from the solvent nozzles 33 to the lower surface of the rotating substrate W held by the spin chuck 2. As a result, the solvent discharged to the lower surface of the substrate W is spread in a ring shape on the lower surface of the substrate W by the centrifugal force due to the rotation of the substrate W.

The solvent spread on the lower surface of the substrate W is scattered from the substrate W by the rotation of the substrate W. Similarly to the pre-wet treatment, the solvent is scattered in the substantially horizontal direction from the rotating substrate W (see FIG. 8). The solvent scattered in the substantially horizontal direction hits the liquid receiving surface 53A of the upper cup 43 and flows down to the base end portion of the middle cup 45, that is, the upper surface 59A of the middle cup 45 on the outer peripheral end side. Then, similarly to the pre-wet treatment, the solvent flows to the drain 71.

Therefore, the solvent can be caused to flow to substantially the entire upper surface 59A of the middle cup 45 every time the back-rinse treatment is performed on the substrate W. As a result, drying of the coating liquid adhering to the upper surface 59A of the middle cup 45 can be suppressed, and the coating liquid can be easily washed off to the lower cup 46.

After a preset amount of the solvent is discharged from the solvent nozzles 33, the on-off valve V3 is closed to stop the discharge of the solvent from the solvent nozzles 33. Thereafter, the rotation mechanism 3 dries the substrate W by rotating the substrate W at preset revolutions per minute. Thereafter, the rotation mechanism 3 stops the rotation of the substrate W held by the spin chuck 2. The coating liquid nozzle 21 and the solvent nozzle 27 are moved to a standby position outside the cup 41 in plan view by the nozzle moving mechanism (not shown).

### Step S05 Release of substrate holding

Thereafter, the spin chuck 2 releases the holding of the substrate W. Thereafter, the lifting and lowering mechanism 87 of the substrate lifting and lowering mechanism 81 lifts the three support pins 83 from the standby position H1 to the transfer position H3. At this time, the three support pins 83 receive the substrate W subjected to the coating treatment and the like from the spin chuck 2 at the holding position H2.

Thereafter, the substrate transfer robot (not shown) moves the hand below the substrate W held by the three support pins 83. Then, the lifting and lowering mechanism 87 lowers the three support pins 83 from the transfer position H3 to the standby position H1. As a result, the hand of the substrate transfer robot receives the substrate W from the three support pins 83. Thereafter, the substrate transfer robot transfers the substrate W to the next destination.

According to the present embodiment, the middle cup 45 is inclined downward from its outer peripheral end portion toward its inner peripheral end portion, and can receive the coating liquid and the solvent that have flowed down along the inner surface of the upper cup 43 on the outer peripheral end portion side of the middle cup 45. In addition, the received coating liquid and solvent are caused to flow downward to the inner peripheral end portion side and guided to the drainage area LA of the lower cup 46. As a result, the solvent received on the inner side surface of the upper cup 43 can be caused to flow to substantially the entire upper surface of the middle cup 45 from the outer peripheral end portion to the inner peripheral end portion of the middle cup 45. Therefore, it is possible to cause the coating liquid and the solvent to flow along the inclination of the middle cup 45 while suppressing drying of the coating liquid adhering to the upper surface of the middle cup 45. As a result, it is possible to suppress the coating liquid from accumulating on the upper surface of the middle cup 45. As a result, a maintenance cycle (for example, a cycle of cup replacement) can be lengthened.

In addition, since the middle cup 45 covers the upper side of the exhaust area GA, it is possible to suppress the coating liquid and the solvent from flowing into the exhaust pipe 69.

In addition, every time the substrate W is treated with the solvent discharged from the solvent nozzles 27 and 33 (at least one of the pre-wet treatment and the back-rinse treatment), the solvent can be supplied to substantially the entire upper surface 59A of the middle cup 45.

In addition, since the outer peripheral end portion of the middle cup 45 is coupled to the inner surface of the upper cup 43, all of the solvent that has flowed down along the inner surface of the upper cup 43 can be caused to flow to substantially the entire upper surface 59A of the middle cup 45.

The upper surface 59A of the middle cup 45 receives the coating liquid scattered from the substrate W when a coating liquid film is formed on the upper surface of the substrate W. On the other hand, the solvent can be caused to flow to substantially the entire upper surface 59A of the middle cup 45.

The middle cup 45 is inclined downward from its outer peripheral end portion toward its inner peripheral end portion. The outer peripheral end portion of the middle cup 45 is coupled to the inner surface of the upper cup 43. In addition, the upper opening 57 is disposed in the central portion of the upper cup 43. As a result, as indicated by an arrow AR5 in FIG. 10, the gas that has flowed in from the upper opening 57 flows in the relatively vertical downward direction toward between the inner peripheral end (distal end member 61) of the middle cup 45 and the inner peripheral wall 65 of the lower cup 46. That is, as indicated by a dashed arrow AR6 in FIG. 10, the gas that has flowed in from the upper opening 57 hardly flows via the inner side surface 51A of the upper cup 43 to between the inner peripheral end of the middle cup 45 and the inner peripheral wall 65 of the lower cup 46. Therefore, the coating liquid and the solvent adhering to the upper surface 59A of the middle cup 45 are hardly dried. Therefore, the coating liquid adhering to the upper surface 59A of the middle cup 45 can be caused to easily flow.

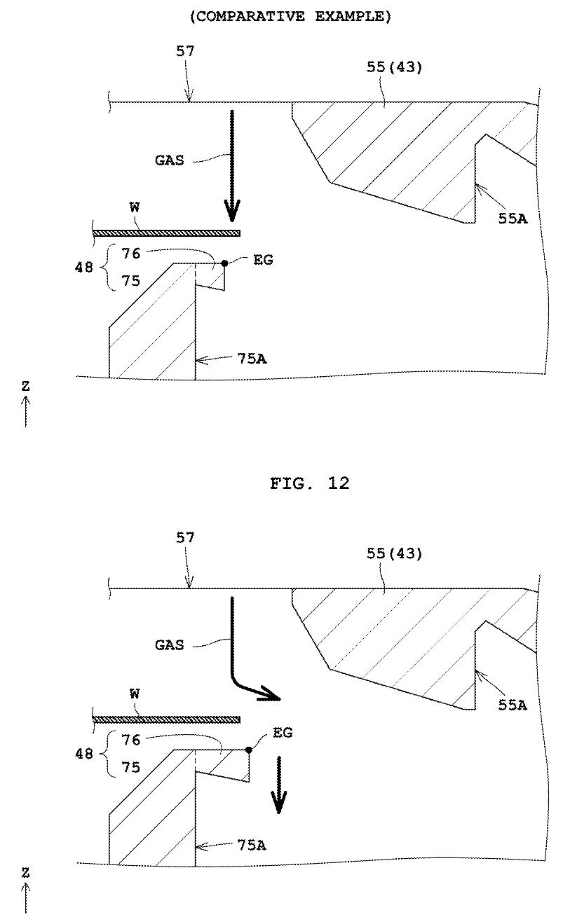

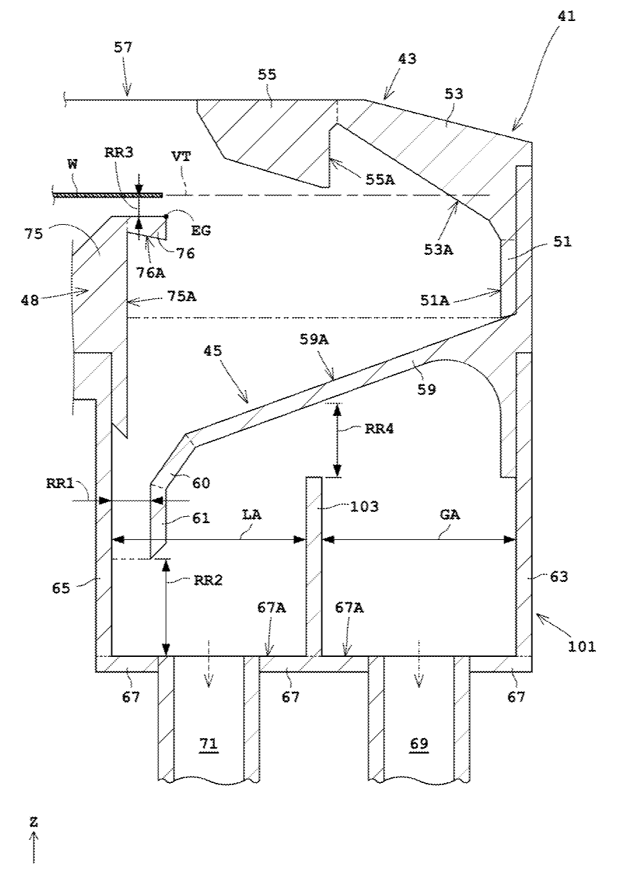

In addition, as indicated by the arrow AR5 in FIG. 10, the gas that has flowed in from the upper opening 57 does not go around and flows in the relatively vertical downward direction toward between the inner peripheral end (distal end member 61) of the middle cup 45 and the inner peripheral wall 65 of the lower cup 46. For example, as shown in FIG. 11, when the outer peripheral end of the substrate W held by the spin chuck 2 protrudes toward an outer peripheral side more than the outer peripheral end EG of the flow straightening member 76, the flow of the gas that has flowed in from the upper opening 57 is disturbed at the outer peripheral end of the substrate W, and this affects the outer peripheral end of the substrate W. As a result, a drying condition of the coating liquid near the outer peripheral end of the substrate W changes, and a thickness of the coating film near the outer peripheral end of the substrate W may change. According to the present embodiment, as shown in FIG. 12, the outer peripheral end EG of the flow straightening member 76 protrudes more than the outer peripheral end of the substrate W held by the spin chuck 2. As a result, the flow of the gas that has flowed in from the upper opening 57 deviates outward from the outer peripheral end of the substrate W. As a result, the change in the drying condition of the coating liquid near the outer peripheral end of the substrate W can be suppressed, whereby the change in the thickness of the coating film near the outer peripheral end of the substrate W can be suppressed.

The trap surface 55A is formed in a cylindrical shape while extending in the vertical direction Z. Therefore, it is possible to easily capture a mist of at least one of the coating liquid and the solvent flowing toward the substrate W held by the spin chuck 2 along the inner surface (side surface 51A) of the outer peripheral wall 51 of the upper cup 43 and the inner surface (liquid receiving surface 53A) of the ceiling wall 53.

The cup 41 (upper cup 43, middle cup 45, lower cup 46, and inner cup 48) is fixed in position so as not to lift and lower with respect to the spin chuck 2. For example, when the cup 41 is configured to lift and lower, the substrate processing apparatus 1 may be increased in size. According to the present embodiment, it is possible to suppress an increase in size of the substrate processing apparatus 1 and to configure the substrate processing apparatus 1 to be relatively compact.

### Second embodiment

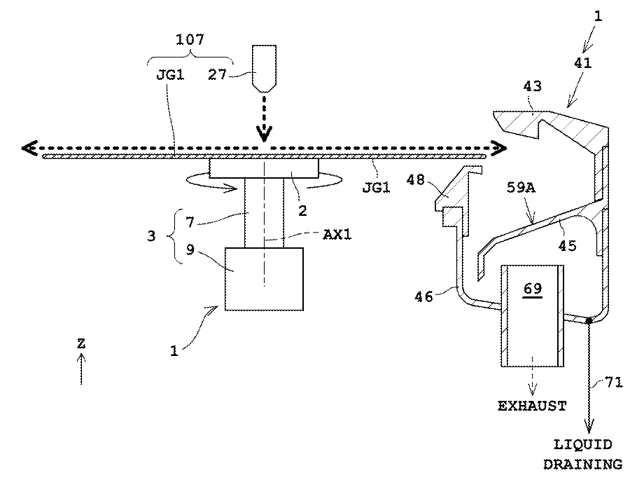

Next, a second embodiment of the present invention will be described with reference to the drawings. Note that descriptions common to the first embodiment will be omitted. FIG. 13 is a longitudinal sectional view showing a cup 41 according to the second embodiment.

In the first embodiment, each exhaust pipe 69 is disposed substantially at the center between the outer peripheral wall 63 and the inner peripheral wall 65 of the lower cup 46, and the drain 71 is disposed on the outer peripheral side of each exhaust pipe 69. In this regard, in the second embodiment, each exhaust pipe 69 may be disposed on an outer peripheral wall 63 side, and a drain 71 may be disposed on an inner peripheral wall 65 side.

Reference is made to FIG. 13. The cup 41 includes a lower cup 101. Similarly to the lower cup 46 shown in FIG. 2, the lower cup 101 is a ring-shaped container provided below an upper cup 43 and having a bottom wall 67. The lower cup 101 includes a partition wall 103 in addition to the outer peripheral wall 63, the inner peripheral wall 65, the bottom wall 67, the exhaust pipe 69, and the drain 71.

The partition wall 103 extends in an upward direction from the bottom wall 67 and is formed in a cylindrical shape. The partition wall 103 is disposed substantially at the center between the outer peripheral wall 63 and the inner peripheral wall 65 in a horizontal direction. Further, the partition wall 103 is disposed between the outer peripheral wall 63 and a distal end member 61 of a middle cup 45. In other words, the distal end member 61 of the middle cup 45 is disposed between the partition wall 103 and the inner peripheral wall 65. A flow path RR4 through which gas to be exhausted passes is formed between an upper end of the partition wall 103 and the middle cup 45 (that is, a middle cup body 59).

A drainage area LA is formed on an inner peripheral side of the partition wall 103. The drainage area LA is a region between the inner peripheral wall 65 of the lower cup 101 and the partition wall 103. The drain 71 is provided on the bottom wall 67 in the drainage area LA on the inner peripheral side of the partition wall 103. On the other hand, an exhaust area GA is formed on an outer peripheral side of the partition wall 103. The exhaust area GA is a region between the partition wall 103 and the outer peripheral wall 63 of the lower cup 101. The exhaust pipe 69 is provided on the bottom wall 67 in the exhaust area GA on the outer peripheral side of the partition wall 103. The partition wall 103 separates liquid (coating liquid and solvent) and gas.

The present embodiment has the same effect as that of the first embodiment. In the lower cup 101, the drain 71 is provided on the inner peripheral side of the partition wall 103. That is, the drain 71 is disposed relatively close to the distal end member 61 of the middle cup 45. Therefore, as shown in FIG. 2, the coating liquid does not flow to the outer peripheral end side of the lower cup 46 along the bottom surface 67A on the inner side of the bottom wall 67 of the lower cup 46. Therefore, the coating liquid can be caused to flow to the drain 71 relatively quickly.

### Third embodiment

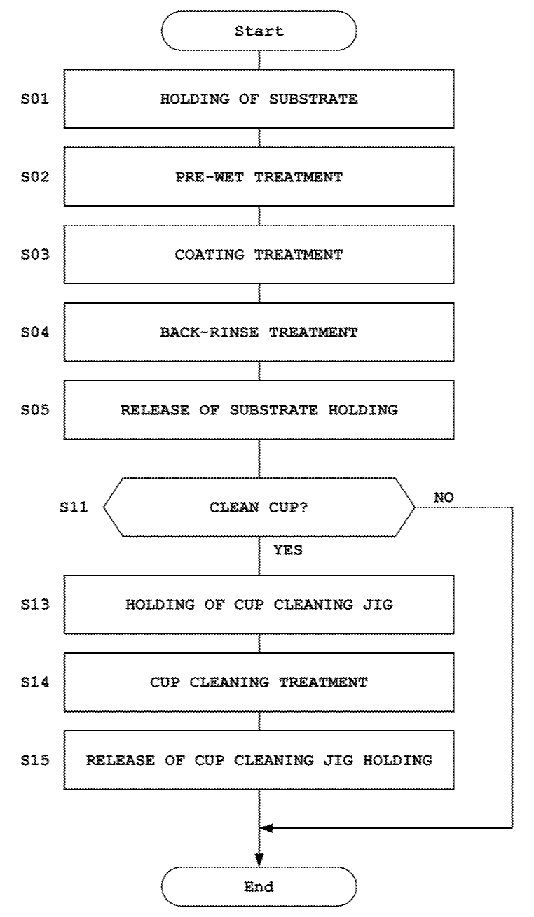

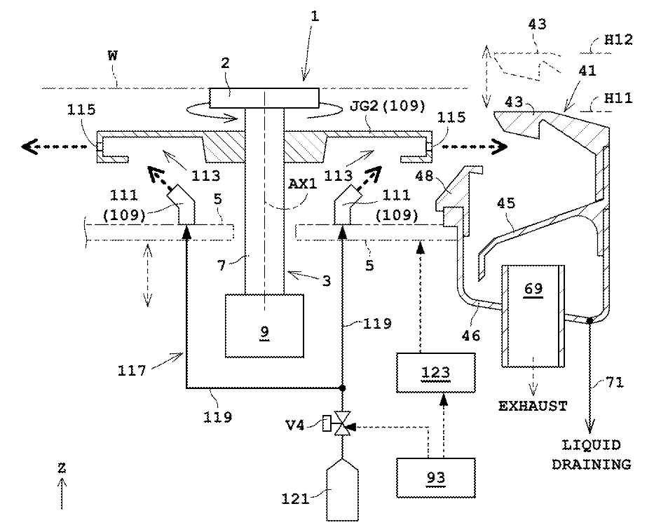

Next, a third embodiment of the present invention will be described with reference to the drawings. Note that descriptions common to the first and second embodiments will be omitted. FIG. 14 is a longitudinal sectional view showing a substrate processing apparatus 1 according to the third embodiment. FIG. 15 is a flowchart showing an example of an operation of the substrate processing apparatus 1 according to the third embodiment.

In the first embodiment, the solvent scattering mechanism 91 includes, for example, the solvent nozzle 27, and the solvent nozzle 27 discharges the solvent to the upper surface of the substrate W held by the spin chuck 2. Here, the substrate W of the first embodiment is a manufacturing substrate for manufacturing a semiconductor or the like. In the third embodiment, a solvent scattering mechanism 107 may include a cup cleaning jig JG1 and a solvent nozzle 27 that discharges a solvent to the cup cleaning jig JG1 held by a spin chuck 2.

Reference is made to FIG. 14. The substrate processing apparatus 1 includes the solvent scattering mechanism 107. The solvent scattering mechanism 107 includes the cup cleaning jig JG1 and the solvent nozzle 27. The cup cleaning jig JG1 is a jig for cleaning an inner surface of a cup 41, and is not a manufacturing substrate. The cup cleaning jig JG1 is formed in a disk shape and held by the spin chuck 2. The cup cleaning jig JG1 may be, for example, a dummy substrate formed of silicon. The cup cleaning jig is also referred to as a cup cleaning disk.

The solvent nozzle 27 discharges the solvent to an upper surface of the cup cleaning jig JG1 held by the spin chuck 2. A rotation mechanism 3 rotates the cup cleaning jig JG1 held by the spin chuck 2 about a vertical axis AX1. As a result, the solvent discharged to the cup cleaning jig JG1 is scattered to an inner side surface of an upper cup 43.

Next, a cup cleaning treatment in step S14 will be described with reference to a flowchart in FIG. 15.

In steps S01 to S05, coating treatment and the like are performed on a substrate W (manufacturing substrate). Note that steps S01 to S05 shown in FIG. 15 are the same as steps S01 to S05 shown in FIG. 7, and thus descriptions thereof will be omitted.

### Step S11 Clean cup?

Information on whether or not to clean the cup 41 is stored in advance in a memory 95. A controller 93 determines to perform the cup cleaning treatment, for example, when the coating treatment and the like are performed on a preset number of substrates W. In addition, the controller 93 may determine to perform the cup cleaning treatment, for example, when a preset time has elapsed from the previous cup cleaning treatment.

When the controller 93 determines to perform the cup cleaning treatment, the processing proceeds to step S13. When the controller 93 determines not to perform the cup cleaning treatment, steps S01 to S05 are performed on the next substrate W.

### Step S13 Holding of cup cleaning jig

A substrate transfer robot (not shown) moves a hand holding the cup cleaning jig JG1 above the spin chuck 2. Thereafter, a lifting and lowering mechanism 87 of a substrate lifting and lowering mechanism 81 lifts three support pins 83 from a standby position H1 to a transfer position H3. As a result, the three support pins 83 receive the substrate W from the substrate transfer robot. Thereafter, the substrate transfer robot moves the hand not holding the substrate W from above the spin chuck 2.

Thereafter, the lifting and lowering mechanism 87 lowers the three support pins 83 from the transfer position H3 to the standby position H1 to place the cup cleaning jig JG1 on an upper surface 2A of the spin chuck 2. Thereafter, the spin chuck 2 holds the cup cleaning jig JG1.

### Step S14 Cup cleaning treatment

The rotation mechanism 3 rotates the cup cleaning jig JG1 held by the spin chuck 2 about the vertical axis AX1 at preset revolutions per minute. By opening an on-off valve V2, the solvent is discharged from the solvent nozzle 27 to the upper surface of the cup cleaning jig JG1 held by the spin chuck 2. As a result, the solvent that has reached the upper surface of the cup cleaning jig JG1 spreads on the upper surface of the cup cleaning jig JG1, and is scattered from an outer peripheral end of the cup cleaning jig JG1 by a centrifugal force.

The solvent is, for example, scattered in a substantially horizontal direction from the rotating cup cleaning jig JG1. The scattered solvent hits a liquid receiving surface 53A of the upper cup 43 and flows down to a base end portion of a middle cup 45, that is, an upper surface 59A of the middle cup 45 on an outer peripheral end side. Therefore, the solvent can be caused to flow to substantially the entire upper surface 59A of the middle cup 45. As a result, the coating liquid adhering to the upper surface 59A of the middle cup 45 can be easily washed off to a lower cup 46.

After a preset time has elapsed, the on-off valve V2 is closed to stop the discharge of the solvent from the solvent nozzle 27. Thereafter, the rotation mechanism 3 dries the cup cleaning jig JG1 by rotating the cup cleaning jig JG1 at preset revolutions per minute. Thereafter, the rotation mechanism 3 stops the rotation of the cup cleaning jig JG1 held by the spin chuck 2.

### Step S15 Release of cup cleaning jig holding

Thereafter, the spin chuck 2 releases the holding of the cup cleaning jig JG1. Thereafter, the lifting and lowering mechanism 87 of the substrate lifting and lowering mechanism 81 lifts the three support pins 83 from the standby position H1 to the transfer position H3. As a result, the three support pins 83 receive the cup cleaning jig JG1 from the spin chuck 2.

Thereafter, the substrate transfer robot (not shown) moves the hand below the cup cleaning jig JG1 supported by the three support pins 83. The lifting and lowering mechanism 87 lowers the three support pins 83 from the transfer position H3 to the standby position H1. As a result, the hand of the substrate transfer robot receives the cup cleaning jig JG1 from the three support pins 83. Thereafter, the substrate transfer robot transfers the cup cleaning jig JG1 from a position above the spin chuck 2.

According to the present embodiment, the same effect as that of the first embodiment is obtained. The middle cup 45 is inclined downward from its outer peripheral end portion toward its inner peripheral end portion. For example, it is assumed that the solvent is supplied to the upper surface 59A of the middle cup 45 using the cup cleaning jig JG1 held by the spin chuck 2 and the solvent nozzle 27. In this case, if the solvent is scattered to the inner side surface of the upper cup 43, the solvent can be caused to flow to substantially the entire upper surface 59A of the middle cup 45. Therefore, it is easy to supply the solvent to the upper surface 59A of the middle cup 45.

### Fourth embodiment

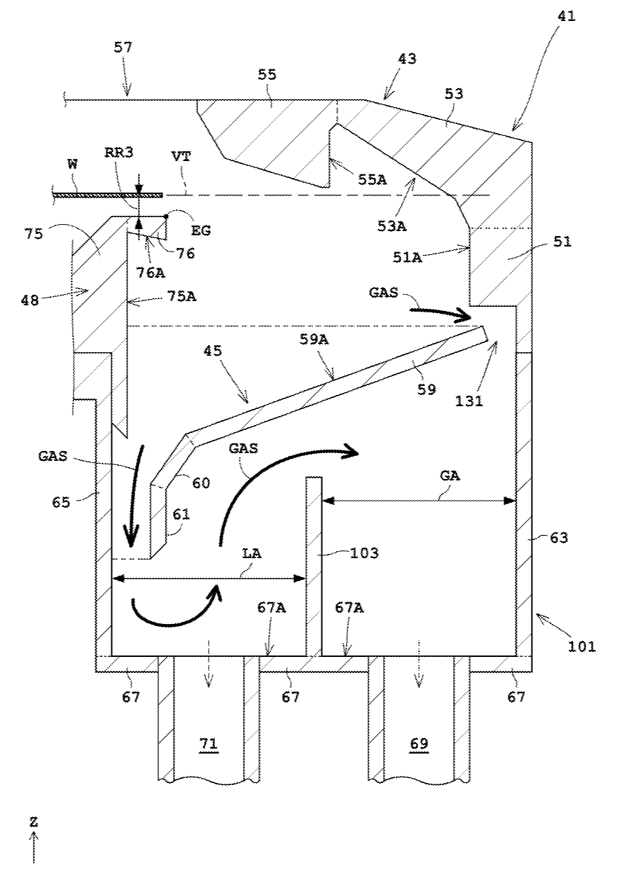

Next, a fourth embodiment of the present invention will be described with reference to the drawings. Note that descriptions common to the first to third embodiments will be omitted. FIG. 16 is a longitudinal sectional view showing a substrate processing apparatus 1 according to the fourth embodiment.

In the third embodiment, the cup cleaning jig JG1 is a member held by the spin chuck 2 and is transferable. In this regard, in the fourth embodiment, a cup cleaning jig JG2 may be provided inside a cup 41.

Reference is made to FIG. 16. A solvent scattering mechanism 109 of the fourth embodiment includes the cup cleaning jig JG2 and two solvent nozzles 111. The cup cleaning jig JG2 is disposed inside the cup 41 (for example, an upper cup 43) and below a spin chuck 2. The cup cleaning jig JG2 is disposed between the spin chuck 2 and a support plate 5 in a vertical direction Z. The cup cleaning jig JG2 is fixed to a rotation shaft 7, for example. As a result, the cup cleaning jig JG2 is rotated about a vertical axis AX1 by a rotation mechanism 3. The cup cleaning jig JG2 may be detachable from the rotation shaft 7.

The cup cleaning jig JG2 includes a single storage portion 113 and a plurality of discharge ports 115. The single storage portion 113 is provided on a lower surface of the cup cleaning jig JG2. The single storage portion 113 receives solvents discharged from the two solvent nozzles 111, and stores the solvents. The single storage portion 113 communicates with the plurality of discharge ports 115. The plurality of discharge ports 115 are provided on a side surface of the cup cleaning jig JG2. The plurality of discharge ports 115 discharge the solvents stored in the single storage portion 113 to the cup 41 by the rotation of the cup cleaning jig JG2.

The substrate processing apparatus 1 includes a third solvent supply mechanism 117. The third solvent supply mechanism 117 includes a solvent pipe 119, an on-off valve V4, and a fourth pump (not shown) in addition to the two solvent nozzles 111. The two solvent nozzles 111 discharge (supply) the solvents to the cup cleaning jig JG2. The two solvent nozzles 111 are provided on an upper surface of the support plate 5. The two solvent nozzles 111 are disposed below the cup cleaning jig JG2. The two solvent nozzles 111 may be provided separately from two solvent nozzles 33 used in a back-rinse treatment.

The solvent pipe 119 is connected to each of the two solvent nozzles 111. A base end of the solvent pipe 119 is connected to a third solvent supply source 121. The on-off valve V4 and the fourth pump are provided in the solvent pipe 119. The fourth pump sends the solvent in the third solvent supply source 121 to each solvent nozzle 111 through the solvent pipe 119. The on-off valve V4 selectively supplies the solvent and stops the supply of the solvent. The number of solvent nozzles 111 may be at least one.

The substrate processing apparatus 1 includes a cup lifting and lowering mechanism 123. The cup lifting and lowering mechanism 123 lifts and lowers the cup 41, the support plate 5, and the like between a cup cleaning position H11 on a lower side and a substrate processing position H12. The cup lifting and lowering mechanism 123 includes an actuator including an electric motor or an air cylinder. The actuator may include a belt like a lifting and lowering mechanism 87 or a screw shaft.

The rotation mechanism 3 rotates the cup cleaning jig JG2 about the vertical axis AX1. As a result, the solvent discharged to the cup cleaning jig JG2 is scattered to an inner side surface of the upper cup 43. The controller 93 shown in FIG. 6 controls the on-off valve V4 and the cup lifting and lowering mechanism 123. In the present embodiment, when the cup 41 is located at the cup cleaning position H11, a substrate W may be transferred to the spin chuck 2. In the case of the present embodiment, the substrate processing apparatus 1 may not include a substrate lifting and lowering mechanism 81.

An operation of the substrate processing apparatus 1 of the fourth embodiment will be briefly described with reference to the flowchart of FIG. 15. In the fourth embodiment, steps S13 and S15 shown in FIG. 15 are not performed. Detailed description of steps S01 to S05 and step S11 will be omitted.

After performing a coating treatment on the substrate W (manufacturing substrate) in steps S01 to S05, the controller 93 determines to clean the cup 41. Therefore, the substrate processing apparatus 1 performs a cup cleaning treatment. The cup 41 is lowered from the substrate processing position H12 to the cup cleaning position H11 by the cup lifting and lowering mechanism 123. Therefore, the plurality of discharge ports 115 of the cup cleaning jig JG2 face a liquid receiving surface 53A of the upper cup 43.

[Step S14] Cup cleaning treatment

The rotation mechanism 3 rotates the cup cleaning jig JG2 about the vertical axis AX1 at preset revolutions per minute. By opening the on-off valve V4, the solvent is discharged from the solvent nozzle 111 to the storage portion 113 provided on the lower surface of the cup cleaning jig JG2. As a result, the solvent discharged to the storage portion 113 is scattered from the plurality of discharge ports 115 by a centrifugal force due to the rotation of the cup cleaning jig JG2.

For example, the solvent is scattered in a substantially horizontal direction from the plurality of discharge ports 115 of the rotating cup cleaning jig JG2. The scattered solvent hits the liquid receiving surface 53A of the upper cup 43 and flows down to a base end portion of a middle cup 45, that is, an upper surface 59A of the middle cup 45 on an outer peripheral end side. Therefore, the solvent can be caused to flow to substantially the entire upper surface 59A of the middle cup 45. As a result, the coating liquid adhering to the upper surface 59A of the middle cup 45 can be easily washed off to a lower cup 46.

After a preset time has elapsed, the on-off valve V4 is closed to stop the discharge of the solvent from the solvent nozzles 111. Thereafter, the rotation mechanism 3 dries the cup cleaning jig JG2 by rotating the cup cleaning jig JG2 at preset revolutions per minute. Thereafter, the rotation mechanism 3 stops the rotation of the cup cleaning jig JG2.

According to the present embodiment, the same effect as that of the first embodiment is obtained. The middle cup 45 is inclined downward from its outer peripheral end portion toward its inner peripheral end portion. For example, it is assumed that the solvent is supplied to the upper surface 59A of the middle cup 45 using the cup cleaning jig JG2 disposed below the spin chuck 2 and the solvent nozzles 111. In this case, if the solvent is scattered to the inner side surface of the upper cup 43, the solvent can be caused to flow to substantially the entire upper surface 59A of the middle cup 45. Therefore, it is easy to supply the solvent to the upper surface 59A of the middle cup 45.

The solvent nozzle 111 corresponds to a second solvent nozzle of the present invention. In the present embodiment, the cup cleaning jig JG2 includes the single storage portion 113 and the plurality of discharge ports 115. In this regard, the cup cleaning jig JG2 may be a dummy substrate.

The present invention is not limited to the above described embodiments, and can be modified as follows.
(1) In the embodiments described above, the liquid receiving surface 53A is formed in the cylindrical shape so as to be inclined in the upward direction from the upper end portion of the side surface 51A of the outer peripheral wall 51 in the inward direction. In this regard, the liquid receiving surface 53A may be formed to extend in the vertical direction Z.
(2) In the embodiments and modification (1) described above, the trap surface 55A is formed to extend in the cylindrical shape in the vertical direction Z. In this regard, the trap surface 55A may be formed in a cylindrical shape so as to extend in the obliquely downward direction toward the vertical axis AX1. In this case, the trap surface 55A is directed in an outward direction and in the obliquely downward direction. When the trap surface 55A extends in the vertical direction Z, the mist is more easily captured. The outward direction is a direction opposite to the inward direction.
(3) In the embodiments and modifications described above, the outer peripheral end portion of the middle cup 45 is coupled to the inner surface of the upper cup 43. In this regard, as shown in FIG. 17, the outer peripheral end portion of the middle cup 45 may not be coupled to the inner surface of the upper cup 43 in some cases. That is, the middle cup 45 may be disposed away from the outer peripheral wall 51 of the upper cup 43 and the outer peripheral wall 63 of the lower cup 46. For example, a ring-shaped vent hole 131 may be formed between the outer peripheral end portion of the middle cup 45 and the outer peripheral wall 51 of the upper cup 43.

The present invention may be embodied in other specific forms without departing from the spirit or essential attributes thereof and, accordingly, reference should be made to the appended claims, rather than to the foregoing specification, as indicating the scope of the invention.

What is claimed is:

1. A substrate processing apparatus configured to apply a coating liquid to a substrate, comprising:
a chuck configured to hold the substrate in a horizontal posture;
a rotation mechanism configured to rotate the chuck about a vertical axis passing through a center of the substrate held by the chuck;
a coating liquid nozzle configured to discharge the coating liquid to an upper surface of the substrate held by the chuck;
a solvent scattering mechanism configured to scatter a solvent outward in a rotation radius direction of the chuck, in cooperation with the rotation mechanism; and
a cup configured to recover the scattered solvent, wherein
the cup includes
an upper cup provided so as to surround a side of the substrate held by the chuck,
a lower cup that is a ring-shaped container provided below the upper cup, a drainage area and an exhaust area being provided separately in the container, and
a middle cup disposed in a ring shape between the upper cup and the lower cup so as to cover an upper side of the exhaust area of the lower cup, and
the middle cup is inclined downward from an outer peripheral end portion of the middle cup toward an inner peripheral end portion of the middle cup, is capable of receiving the coating liquid and the solvent that have flowed down along an inner surface of the upper cup on a side of the outer peripheral end portion, and is configured to cause the received coating liquid and the solvent to flow downward to a side of the inner peripheral end portion to be guided to the drainage area of the lower cup.

2. The substrate processing apparatus according to claim 1, wherein
the outer peripheral end portion of the middle cup is coupled to the inner surface of the upper cup.

3. The substrate processing apparatus according to claim 1, wherein
the middle cup is configured to form a gap between the inner peripheral end portion of the middle cup and an inner peripheral wall of the lower cup.

4. The substrate processing apparatus according to claim 3, wherein
the gap is located below an outer peripheral end of the substrate.

5. The substrate processing apparatus according to claim 3, wherein
the middle cup is configured to form the gap extending in a downward direction with the inner peripheral wall of the lower cup as a distal end of the inner peripheral end portion of the middle cup hangs down in a vertical downward direction.

6. The substrate processing apparatus according to claim 1, wherein
the solvent scattering mechanism includes a first solvent nozzle configured to discharge the solvent to the substrate held by the chuck, and
the rotation mechanism is configured to rotate the substrate held by the chuck about the vertical axis to scatter the solvent discharged to the substrate to an inner side surface of the upper cup.

7. The substrate processing apparatus according to claim 1, wherein
the solvent scattering mechanism includes
a cup cleaning jig formed in a disk shape, and
a first solvent nozzle configured to discharge the solvent to the cup cleaning jig held by the chuck, and
the rotation mechanism is configured to rotate the cup cleaning jig held by the chuck about the vertical axis to scatter the solvent discharged to the cup cleaning jig to an inner side surface of the upper cup.

8. The substrate processing apparatus according to claim 1, wherein
the solvent scattering mechanism includes
a cup cleaning jig disposed inside the upper cup and below the chuck, and
a second solvent nozzle configured to supply the solvent to the cup cleaning jig, and
the rotation mechanism is configured to rotate the cup cleaning jig about the vertical axis to scatter the solvent supplied to the cup cleaning jig to an inner side surface of the upper cup.

9. The substrate processing apparatus according to claim 1, wherein
the lower cup includes
a bottom wall,
an exhaust pipe provided on the bottom wall in the exhaust area, and
a drain provided on the bottom wall in the drainage area, and
the drain is disposed on an outer peripheral side of the exhaust pipe.

10. The substrate processing apparatus according to claim 1, wherein
the upper cup includes an upper opening disposed in an upper portion and a central portion of the upper cup,
the outer peripheral end portion of the middle cup is coupled to the inner surface of the upper cup,
the lower cup includes
a bottom wall,
an exhaust pipe provided on the bottom wall in the exhaust area,
a drain provided on the bottom wall in the drainage area, and
an inner peripheral wall extending in a cylindrical shape in an upward direction from the bottom wall, and
the exhaust pipe is configured to exhaust gas that has flowed in from the upper opening of the upper cup and passed between the inner peripheral end portion of the middle cup and the inner peripheral wall of the lower cup.

11. The substrate processing apparatus according to claim 10, wherein
the cup includes an inner cup configured to extend in a cylindrical shape in the upward direction from an upper end of the inner peripheral wall of the lower cup toward a lower surface of the substrate held by the chuck,
the inner cup includes
an inner cup body formed in a cylindrical shape, and
a flow straightening member formed in a ring shape at an upper end portion of the inner cup body, and
an outer peripheral end of the flow straightening member is configured to protrude toward an outer peripheral side more than an outer peripheral end of the substrate held by the chuck.

12. The substrate processing apparatus according to claim 1, wherein
the upper cup includes
an outer peripheral wall formed in a cylindrical shape, and
a ceiling wall formed in a ring shape while extending in an inward direction from an upper portion of the outer peripheral wall toward the vertical axis,
the ceiling wall includes a trap portion formed in a ring shape in an inner peripheral portion and configured to protrude in a downward direction, and
a trap surface is formed on an outer peripheral side of the trap portion.

13. The substrate processing apparatus according to claim 1, wherein
the cup is fixed in position so as not to lift and lower with respect to the chuck.

14. The substrate processing apparatus according to claim 13, further comprising:
at least three support pins provided around the vertical axis and configured to support the substrate, the at least three support pins being disposed on an outer peripheral side of the chuck and on an inner peripheral side of the upper cup; and
a support pin lifting and lowering mechanism configured to lift and lower the at least three support pins, wherein
the upper cup includes an upper opening disposed in an upper portion and a central portion of the upper cup, and
the support pin lifting and lowering mechanism is configured to lift and lower the substrate between a holding position of an upper surface of the chuck and a transfer position higher than an upper end of the upper cup, through the upper opening.
